(19) United States
(12) Patent Application Publication
(10) Pub. No.: US 2025/0167079 A1
(43) Pub. Date: May 22, 2025

(54) SEMICONDUCTOR DEVICE

(71) Applicant: Mitsubishi Electric Corporation, Tokyo (JP)

(72) Inventors: Ryoji MURAI, Fukuoka (JP); Hideo KOMO, Tokyo (JP); Naoki YOSHIMATSU, Tokyo (JP)

(73) Assignee: Mitsubishi Electric Corporation, Tokyo (JP)

(21) Appl. No.: 18/839,925

(22) PCT Filed: Apr. 26, 2022
(86) PCT No.: PCT/JP2022/018852

§ 371 Date: Aug. 20, 2024

(51) Int. Cl. H01L 23/495; H01L 23/00

(52) U.S. Cl. CPC H01L 23/49524; H01L 24/40; H01L 2224/4005; H01L 2224/40249; H01L 2924/1815

(57) ABSTRACT

An increase in size of a device is suppressed. A semiconductor device includes: a P electrode provided to extend outward from a first side surface of a substrate; an AC electrode provided to extend outward from a second side surface opposite the first side surface; a first connecting electrode and a second connecting electrode each provided to extend outward from at least one of a third side surface intersecting with the first side surface and a fourth side surface opposite the third side surface, wherein the first connecting electrode does not overlap any of the P electrode and the AC electrode above the substrate, and the second connecting electrode does not overlap any of the P electrode and the AC electrode above the substrate.

### TECHNICAL FIELD

Technology disclosed herein relates to power semiconductor technology.

### BACKGROUND ART

A conventional power device module includes a P electrode, an N electrode, and an AC electrode. Each of the electrodes is provided to a first side surface outside a framework of the power device module or a second side surface opposite the first side surface.

When a plurality of power device modules are used by being connected in parallel, AC electrodes of the power device modules connected in parallel are wired, and N electrodes of the power device modules connected in parallel are wired, so that an oscillation phenomenon can be suppressed.

When the plurality of power device modules are used by being connected in parallel, other power device modules are generally arranged to oppose a third side surface perpendicular to each of the first side surface and the second side surface and a fourth side surface opposite the third side surface.

The AC electrodes or the N electrodes are thus provided to the third side surface and the fourth side surface opposing each other to facilitate wiring between the AC electrodes or between the N electrodes of the power device modules connected in parallel.

For example, as illustrated in Patent Document 1, power device modules each including an AC electrode and an N electrode provided to a side surface perpendicular to a side surface to which a P electrode and an N electrode are provided are arranged so that side surfaces to which AC electrodes and N electrodes are provided oppose each other. This facilitates wiring between the AC electrodes and between the N electrodes of adjacent power device modules to suppress an oscillation phenomenon.

### PRIOR ART DOCUMENTS

### Patent Document

Patent Document 1: Japanese Patent Application Laid-Open No. 2019-169609

### SUMMARY

### Problem to be Solved by the Invention

In a structure shown in Patent Document 1, electrodes are wired while overlapping each other in plan view in a sealing resin of a power device module. The electrodes wired to overlap each other in plan view are required to be away from each other to maintain insulation. This results in a problem of an increase in size of a device.

Technology disclosed herein has been conceived in view of a problem as described above and is technology to suppress an increase in size of a device while facilitating wiring when devices are used by being connected in parallel.

### Means to Solve the Problem

A semiconductor device as a first aspect of technology disclosed herein includes: a substrate; at least one semiconductor element provided over an upper surface of the substrate; a P electrode electrically connected to the semiconductor element and provided to extend outward from a first side surface of the substrate in plan view; an AC electrode electrically connected to the semiconductor element and provided to extend outward from a second side surface opposite the first side surface in plan view; a first connecting electrode electrically connected to the semiconductor element and the AC electrode and provided to extend outward from at least one of a third side surface intersecting with the first side surface and a fourth side surface opposite the third side surface in plan view; and a second connecting electrode electrically connected to the semiconductor element and provided to extend outward from at least one of the third side surface and the fourth side surface in plan view, wherein the first connecting electrode does not overlap any of the P electrode and the AC electrode in plan view above the substrate, and the second connecting electrode does not overlap any of the P electrode and the AC electrode in plan view above the substrate.

### Effects of the Invention

According to at least the first aspect of technology disclosed herein, the connecting electrodes are provided to the side surfaces intersecting with the side surfaces to which the P electrode and the AC electrode are provided to facilitate wiring while oscillation is suppressed when the components are used by being connected in parallel. The connecting electrodes are provided not to overlap any of the P electrode and the AC electrode in plan view above the substrate to enable miniaturization of a device.

These and other objects, features, aspects and advantages relating to technology disclosed herein will become more apparent from the following detailed description when taken in conjunction with the accompanying drawings.

### BRIEF DESCRIPTION OF DRAWINGS

FIG. 1 is a plan view illustrating an example of a configuration of a semiconductor device according to an embodiment.

FIG. 2 is a plan view illustrating an example of a configuration of a semiconductor device according to an embodiment.

FIG. 3 is a plan view illustrating an example of a configuration of semiconductor devices according to an embodiment.

FIG. 4 is a perspective view illustrating an example of a configuration of a semiconductor device according to an embodiment.

FIG. 5 is a perspective view illustrating an example of a configuration of a semiconductor device according to an embodiment.

FIG. 6 is a side view of the configuration illustrated in the figure.

FIG. 7 is a perspective view illustrating an example of a configuration of a semiconductor device according to an embodiment.

FIG. 8 is a side view illustrating an example of a configuration of a semiconductor device according to an embodiment.

FIG. 9 is a side view illustrating an example of a configuration of semiconductor devices according to an embodiment.

FIG. 10 is a plan view illustrating an example of a configuration of semiconductor devices according to an embodiment.

FIG. 11 is a plan view illustrating an example of a configuration of a semiconductor device.

### DESCRIPTION OF EMBODIMENTS

Embodiments will be described below with reference the accompanying drawings. While detailed features and the like are shown in the embodiments below for description of technology, they are examples and are not necessary features to implement the embodiments.

The drawings are schematically shown, and components are omitted or simplified in the drawings as appropriate for convenience of description. The sizes of and a positional interrelationship among components and the like shown in different drawings are not necessarily accurate and can be changed as appropriate. Hatching is sometimes applied to drawings other than a cross-sectional view, such as a plan view, for ease of understanding of the embodiments.

In description made below, similar components bear the same reference signs and have similar names and functions. Detailed description thereof is thus sometimes omitted to avoid redundancy.

In description made herein, an expression “comprising”, “including”, or “having” a certain component is not an exclusive expression excluding the presence of the other components unless otherwise noted.

In description made herein, ordinal numbers, such as “first” and “second”, are used for the sake of convenience for ease of understanding of the embodiments, and the order is not limited to that can be represented by the ordinal numbers.

In description made herein, terms representing specific positions or directions, such as “upper”, “lower”, “left”, “right”, “side”, “bottom”, “front”, and “back”, may be used, but these terms are used for the sake of convenience for ease of understanding of the embodiments and do not relate to positions or directions in actual implementation.

In description made herein, a phrase “an upper surface of . . . ” or “a lower surface of . . . ” includes not only an upper surface or a lower surface of a target component itself but also a state of another component being formed on the upper surface or the lower surface of the target component. That is to say, a phrase “A provided on an upper surface of B” does not prevent another component “C” from being interposed between A and B.

### First Embodiment

A semiconductor device according to the present embodiment will be described below. A configuration of a semiconductor device known by the inventors will be described first for convenience of description.

In description made below, an expression “A and B are electrically connected” means that a current can flow bidirectionally between components A and B.

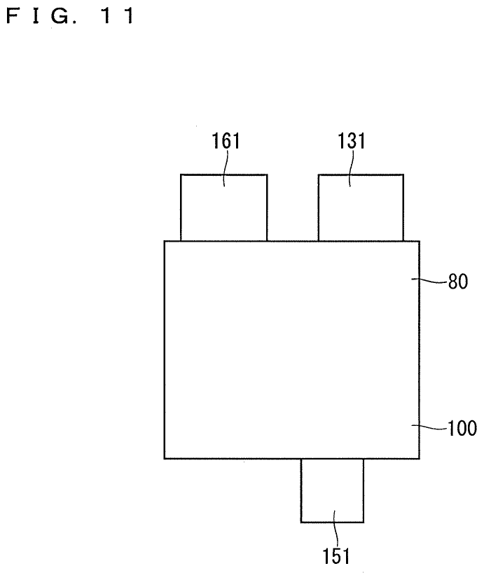

FIG. 11 is a plan view illustrating an example of a configuration of a semiconductor device. The semiconductor device illustrated in FIG. 11 includes an N electrode 161, a P electrode 131, and an AC electrode 151 provided to protrude outward of a frame of a substrate 100 while being partially covered with a resin 80.

The N electrode 161 and the P electrode 131 are herein provided outward of a frame of a first side surface of the substrate 100. On the other hand, the AC electrode 151 is provided outward of a frame of a second side surface opposite the first side surface.

### <Configuration of Semiconductor Device>

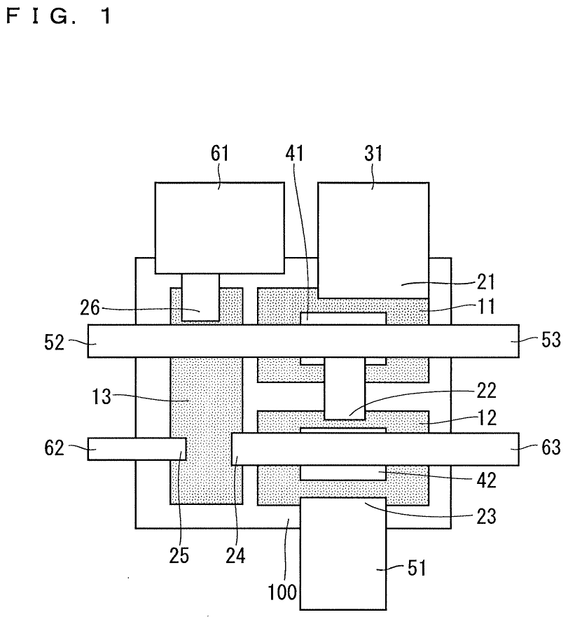

FIG. 1 is a plan view illustrating an example of a configuration of a semiconductor device according to the present embodiment. As illustrated in FIG. 1, the semiconductor device includes a metal layer 11, a metal layer 12, and a metal layer 13 formed over an upper surface of the substrate 100 to be spaced apart from one another.

A P electrode 31 is joined to an upper surface of the metal layer 11 via a joint 21. A semiconductor element 41 is joined to the upper surface of the metal layer 11. That is to say, the P electrode 31 is electrically connected to the semiconductor element 41 via the metal layer 11. An AC electrode 53 is joined to an upper surface of the semiconductor element 41. The AC electrode 53 is wired (connected) to an AC electrode 52. The AC electrode 53 is joined to the metal layer 12 via a joint 22.

An AC electrode 51 is joined to an upper surface of the metal layer 12 via a joint 23. That is to say, the AC electrode 53 is electrically connected to the AC electrode 51 via the metal layer 12. A semiconductor element 42 is joined to the upper surface of the metal layer 12. That is to say, the AC electrode 51 is electrically connected to the semiconductor element 42 via the metal layer 12. An N electrode 63 is joined to an upper surface of the semiconductor element 42. The N electrode 63 is joined to the metal layer 13 via a joint 24.

An N electrode 62 is joined to an upper surface of the metal layer 13 via a joint 25. An N electrode 61 is joined to the upper surface of the metal layer 13 via a joint 26. The N electrode 61 is electrically connected to the semiconductor element 42 via the metal layer 13 and the N electrode 63.

The P electrode, the N electrodes, and the AC electrodes (output terminals) are herein lead terminals for use in the semiconductor device, for example. The lead terminals are generally supplied as a lead frame having been stamped in a predetermined pattern from a strip-like thin metal plate and are disconnected from the frame after undergoing necessary processing.

The P electrode 31 and the N electrode 61 are provided outward of a frame of a first side surface of the substrate 100. The AC electrode 51 is provided outward of a frame of a second side surface opposite the first side surface.

The AC electrode 52 and the N electrode 62 are provided outward of a frame of a third side surface perpendicular to the first side surface. The AC electrode 53 and the N electrode 63 are provided outward of a frame of a fourth side surface opposite the third side surface.

According to such a configuration, the AC electrode 52 and the AC electrode 53 are electrically connected to the AC electrode 51 via the metal layer 12. Furthermore, the N electrode 62 and the N electrode 63 are electrically connected to the N electrode 61 via the metal layer 13.

More particularly, the AC electrode 52 and the AC electrode 53 are arranged not to overlap any of the P electrode 31, the AC electrode 51, and the N electrode 61 in plan view above the substrate 100 overlapping the substrate 100 in plan view. Similarly, the N electrode 62 and the N electrode 63 are arranged not to overlap any of the P electrode 31, the AC electrode 51, and the N electrode 61 in plan view above the substrate 100 overlapping the substrate 100 in plan view.

Thus, the AC electrode 52 and the N electrode 62 can be provided outward of the frame of the third side surface, and the AC electrode 53 and the N electrode 63 can be provided outward of the frame of the fourth side surface with the electrodes not stereoscopically intersecting with one another (i.e., not overlapping in plan view) within the frame of the substrate 100.

In other words, the AC electrode 52, the AC electrode 53, the N electrode 62, and the N electrode 63 are provided at positions where they do not overlap the P electrode 31 in plan view above the substrate 100 overlapping the substrate 100 in plan view. Furthermore, the AC electrode 52, the AC electrode 53, the N electrode 62, and the N electrode 63 are provided at positions where they do not overlap the AC electrode 51 in plan view above the substrate 100 overlapping the substrate 100 in plan view. Furthermore, the AC electrode 52, the AC electrode 53, the N electrode 62, and the N electrode 63 are provided at positions where they do not overlap the N electrode 61 in plan view above the substrate 100 overlapping the substrate 100 in plan view.

The number of semiconductor elements of the semiconductor device is only required to be at least one.

### Second Embodiment

A semiconductor device according to the present embodiment will be described below. In description made below, similar components to those described in the embodiment described above bear the same reference signs as those of the similar components, and detailed description thereof will be omitted as appropriate.

### <Configuration of Semiconductor Device>

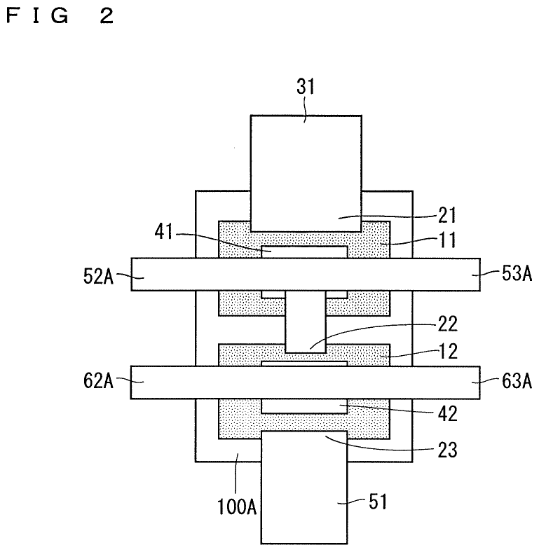

FIG. 2 is a plan view illustrating an example of a configuration of the semiconductor device according to the present embodiment. As illustrated in FIG. 2, the semiconductor device includes the metal layer 11 and the metal layer 12 formed over an upper surface of a substrate 100A to be spaced apart from each other.

The P electrode 31 is joined to the upper surface of the metal layer 11 via the joint 21. The semiconductor element 41 is joined to the upper surface of the metal layer 11. An AC electrode 53A is joined to the upper surface of the semiconductor element 41. The AC electrode 53A is wired (connected) to an AC electrode 52A. The AC electrode 53A is joined to the metal layer 12 via the joint 22.

The AC electrode 51 is joined to the upper surface of the metal layer 12 via the joint 23. The semiconductor element 42 is joined to the upper surface of the metal layer 12. An N electrode 63A is joined to the upper surface of the semiconductor element 42. The N electrode 63A is wired (connected) to an N electrode 62A.

The P electrode 31 is provided outward of a frame of a first side surface of the substrate 100A. The AC electrode 51 is provided outward of a frame of a second side surface opposite the first side surface.

The AC electrode 52A and the N electrode 62A are provided outward of a frame of a third side surface perpendicular to the first side surface. The AC electrode 53A and the N electrode 63A are provided outward of a frame of a fourth side surface opposite the third side surface.

According to such a configuration, the AC electrode 52A and the AC electrode 53A are electrically connected to the AC electrode 51 via the metal layer 12.

Thus, the AC electrode 52A and the N electrode 62A can be provided outward of the frame of the third side surface, and the AC electrode 53A and the N electrode 63A can be provided outward of the frame of the fourth side surface with the electrodes not stereoscopically intersecting with one another (i.e., not overlapping in plan view) within the frame of the substrate 100. The N electrode is not provided to the first side surface to enable miniaturization of the device.

### Third Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

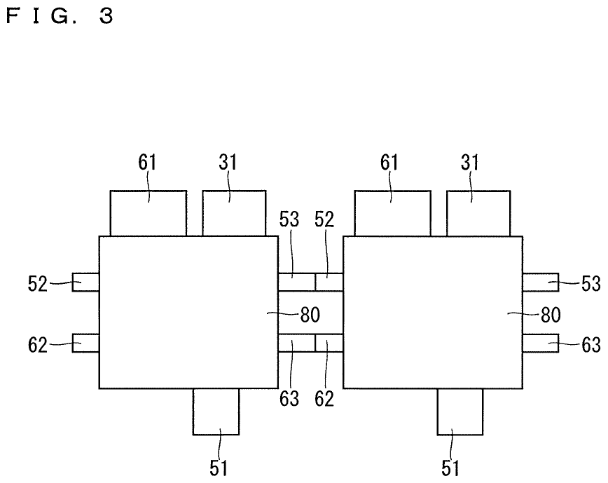

FIG. 3 is a plan view illustrating an example of a configuration of semiconductor devices according to the present embodiment. The configuration illustrated in FIG. 3 corresponds to a configuration in which a plurality of substrates 100 each having the configuration illustrated in FIG. 1 are arranged adjacent to each other so that the third side surface and the fourth side surface oppose each other with the configuration being partially covered with a resin 80 above the upper surface of the substrate 100, specifically, with the semiconductor element 41, the semiconductor element 42, a portion of the P electrode 31, a portion of the N electrode 61, a portion of the AC electrode 52, a portion of the AC electrode 53, a portion of the N electrode 62, a portion of the N electrode 63, and a portion of the AC electrode 51 corresponding to each of the substrates 100 being covered with the resin 80.

In the configuration illustrated in FIG. 3, the AC electrode 52, the AC electrode 53, the N electrode 62, and the N electrode 63 are provided at positions where they do not overlap the P electrode 31 in plan view in the resin 80. Furthermore, the AC electrode 52, the AC electrode 53, the N electrode 62, and the N electrode 63 are provided at positions where they do not overlap the AC electrode 51 in plan view in the resin 80. Furthermore, the AC electrode 52, the AC electrode 53, the N electrode 62, and the N electrode 63 are provided at positions where they do not overlap the N electrode 61 in plan view in the resin 80.

As illustrated in FIG. 3, the AC electrode 52 on the third side surface and the AC electrode 53 on the fourth side surface of the substrates 100 arranged adjacent to (opposite) each other are joined (i.e., the AC electrodes on the opposite side surfaces are connected), and the N electrode 62 on the third side surface and the N electrode 63 on the fourth side surface of the substrates 100 arranged adjacent to (opposite) each other are joined (i.e., the N electrodes on the opposite side surfaces are connected). These electrodes are joined by welding, bolting, or soldering, for example.

According to such a configuration, oscillation of semiconductor elements of a plurality of power device modules connected in parallel can be suppressed.

### Fourth Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

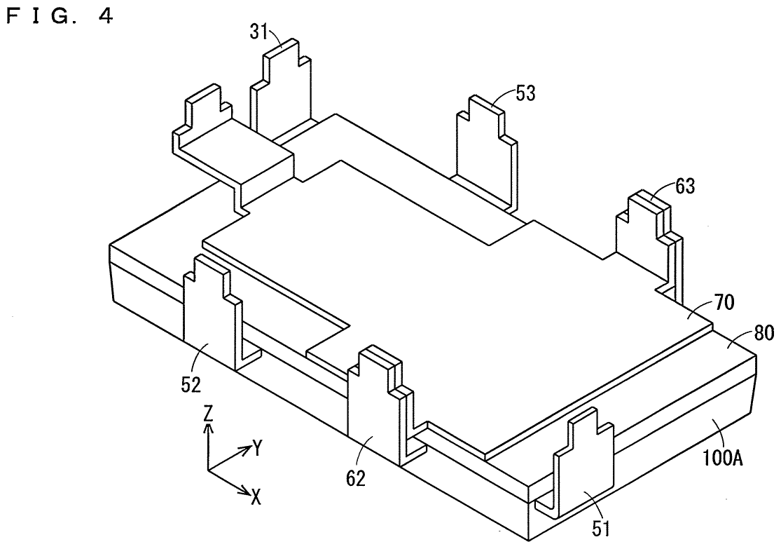

FIG. 4 is a perspective view illustrating an example of a configuration of the semiconductor device according to the present embodiment. A structure illustrated in FIG. 4 is a structure in which the resin 80 is formed above the structure illustrated in FIG. 2, and, further, an N bus bar 70 is provided over an upper surface of the resin 80.

As illustrated in FIG. 4, the N bus bar 70 is joined to each of the N electrode 62 and the N electrode 63. The N bus bar 70 is formed to extend to a position adjacent to the P electrode 31 provided outward of the frame of the first side surface of the substrate 100A.

According to such a configuration, the N bus bar 70 is located at a top of the semiconductor device, so that the N bus bar 70 over the upper surface of the resin 80 is a flat plate parallel to wiring in the resin 80. Inductance can thereby be suppressed.

### Fifth Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

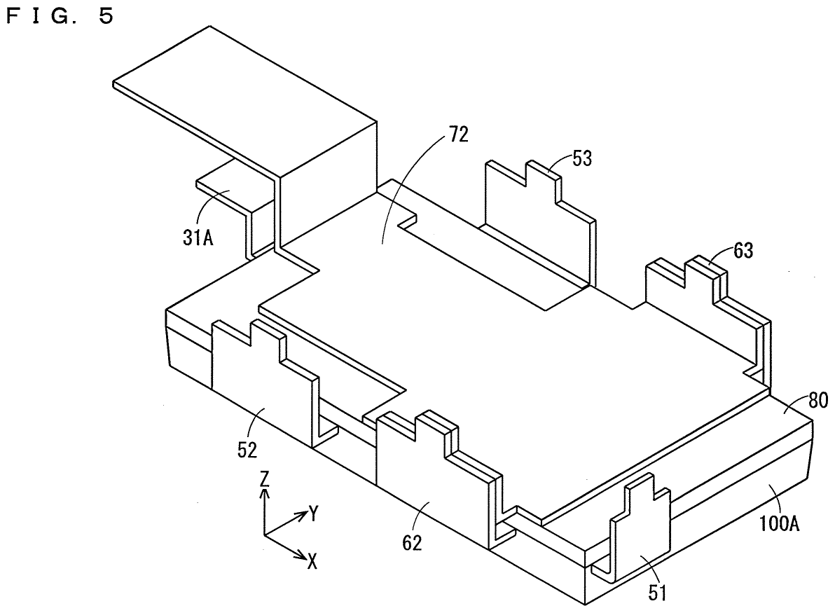

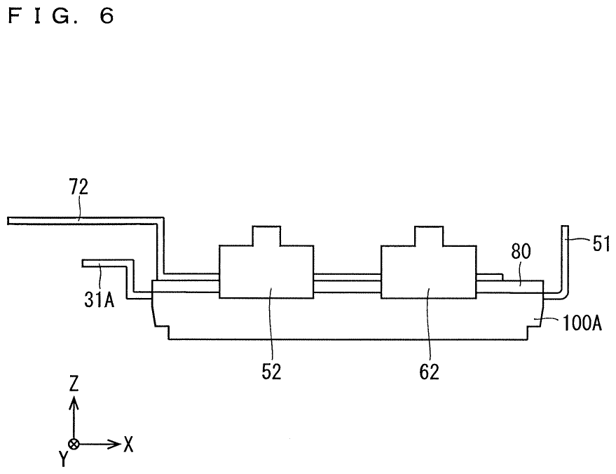

FIG. 5 is a perspective view illustrating an example of a configuration of the semiconductor device according to the present embodiment. A structure illustrated in FIG. 5 is a structure in which the resin 80 is formed above the structure illustrated in FIG. 2 (although a shape of a P electrode 31A has been deformed), and, further, an N bus bar 72 is provided over the upper surface of the resin 80. FIG. 6 is a side view of the configuration illustrated in FIG. 5.

As illustrated in FIGS. 5 and 6, the N bus bar 72 is joined to each of the N electrode 62 and the N electrode 63. The N bus bar 72 is formed to extend to be a flat plate parallel to the P electrode 31A outside the frame of the first side surface of the substrate 100A. That is to say, the N bus bar 72 is disposed to overlap the P electrode 31A in plan view outside the frame of the first side surface.

According to such a configuration, inductance can effectively be suppressed. The N electrode 61 and the P electrode 31 illustrated in FIG. 1 may be arranged to overlap each other in plan view outside the frame of the first side surface.

### Sixth Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

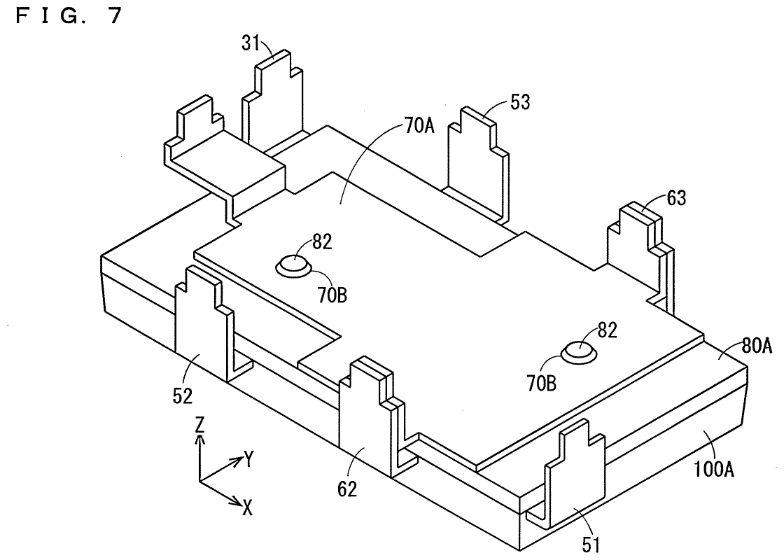

FIG. 7 is a perspective view illustrating an example of a configuration of the semiconductor device according to the present embodiment. A structure illustrated in FIG. 7 is a structure in which a resin 80A is formed above the structure illustrated in FIG. 2, and, further, an N bus bar 70A is provided over an upper surface of the resin 80.

As illustrated in FIG. 7, the N bus bar 70A is joined to each of the N electrode 62 and the N electrode 63. The N bus bar 70A is formed to extend to a position adjacent to the P electrode 31 provided outward of the frame of the first side surface of the substrate 100A.

The N bus bar 70A has a plurality of holes 70B. Relative positions of the N bus bar 70A and the resin 80A are determined so that a plurality of protrusions 82 formed on the upper surface of the resin 80A are fitted into the holes 70B (i.e., the protrusions 82 overlap the holes 70B in plan view). The number of protrusions 82 and the number of holes 70B may each one.

According to such a configuration, the relative positions of the N bus bar 70A and the resin 80A are determined by the holes 70B and the protrusions 82, so that misalignment in assembly of the semiconductor device can be suppressed.

### Seventh Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

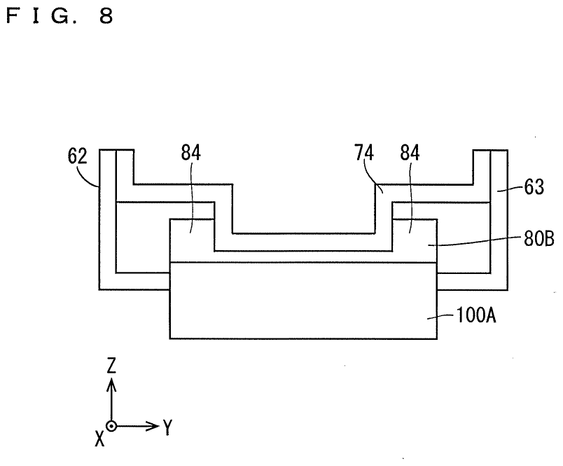

FIG. 8 is a side view illustrating an example of a configuration of the semiconductor device according to the present embodiment. A structure illustrated in FIG. 8 is a structure in which a shape of the resin in the structure illustrated in FIG. 4 has been deformed.

As illustrated in FIG. 8, a resin 80B has guides 84 on an upper surface thereof. The guides 84 are protruding portions on the upper surface of the resin 80B. An N bus bar 74 is joined to each of the N electrode 62 and the N electrode 63. The N bus bar 74 is herein disposed over the upper surface of the resin 80B adjacent to the guides 84 at a position where the N bus bar 74 is sandwiched between the guides 84 in plan view. Specifically, the N bus bar 74 is disposed over the upper surface of the resin 80B while being sandwiched between the two guides 84 to be fixed. The N bus bar 74 may be surrounded by a circumferentially continuous guide 84. Both the protrusions 82 illustrated in FIG. 7 and the guides 84 may be provided.

According to such a configuration, the N bus bar 74 is positioned by being fitted between the guides 84, so that misalignment in assembly of the semiconductor device can be suppressed. An insulating strength can be improved when a long creepage distance between the N bus bar 74 and the AC electrode is maintained by forming the guides 84.

### Eighth Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

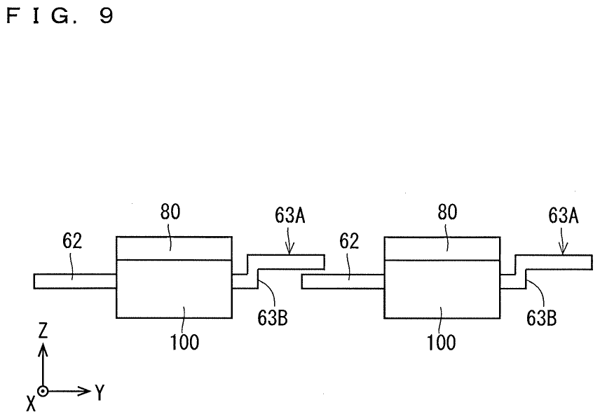

FIG. 9 is a side view illustrating an example of a configuration of semiconductor devices according to the present embodiment. A structure illustrated in FIG. 9 is a structure in which a shape of at least one of the AC electrode and the N electrode in the structure illustrated in FIG. 1 has been deformed.

As illustrated in FIG. 9, the N electrode 63A has a bend 63B so that a height of an end connected to the N electrode 62 of an adjacent power device module can be reduced. The bend 63B bends (moves) the end of the N electrode 63A to a side of the upper surface of the substrate 100 by a thickness of the N electrode 63A, for example.

According to such a configuration, good insulation between a part installed at a top of the semiconductor device and the N electrode 63A can be maintained by ensuring a sufficient insulating distance. The part installed at the top of the semiconductor device includes a bus bar, a control board, and the like.

While a case where the N electrode 63A has the bend 63B has been shown in description made above, an electrode having a bend may be the N electrode 62, the AC electrode 52, the AC electrode 53, and the like. Each of an electrode provided outward of the frame of the third side surface and an electrode provided outward of the frame of the fourth side surface may have a bend.

### Ninth Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

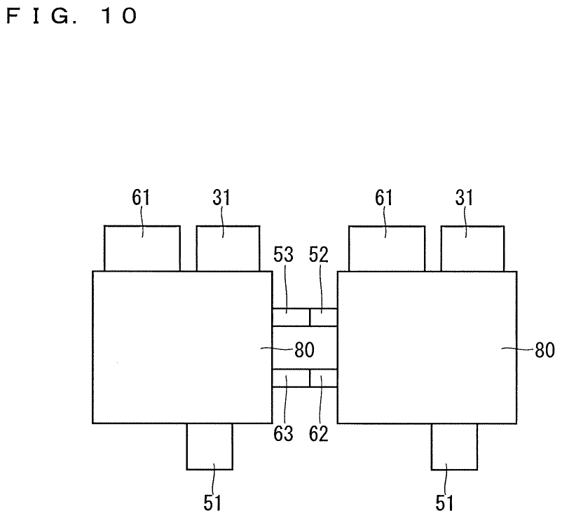

FIG. 10 is a plan view illustrating an example of a configuration of semiconductor devices according to the present embodiment. A structure illustrated in FIG. 10 is a structure in which, in the structure illustrated in FIG. 3, electrodes not connected to their counterparts of an adjacent power device module, that is, an unjoined AC electrode 52 on the third side surface, an unjoined AC electrode 53 on the fourth side surface, an unjoined N electrode 62 on the third side surface, and an unjoined N electrode 63 on the fourth side surface in FIG. 3 are not arranged outward of the frames of the side surfaces at the respective positions. At least one electrode not connected to its counterpart of an adjacent power device module is only required to be not joined, and the configuration is not limited to a configuration in which all the electrodes not connected to their counterparts of the adjacent power device module are not joined as illustrated in FIG. 10.

According to such a configuration, good insulation can be maintained on surfaces on which the N electrode and the AC electrode are not provided. Even when another device is disposed to oppose a surface on which the N electrode and the AC electrode are not provided, there is no need to separately consider the insulating distance, so that an increase in size of the device can be suppressed.

### Tenth Embodiment

A semiconductor device according to the present embodiment will be described below. In description made below, similar components to those described in the embodiments described above bear the same reference signs as those of the similar components, and detailed description thereof will be omitted as appropriate.

### <Configuration of Semiconductor Device>

In any of the embodiments described above, the semiconductor element may include SiC.

### <Effects Produced by Embodiments Described Above>

Examples of effects produced by the embodiments described above will be shown next. In description made below, the effects will be described based on a specific configuration whose examples are shown in the embodiments described above, but the specific configuration may be replaced with another specific configuration whose example is shown herein to the extent that similar effects are produced. That is to say, only one of corresponding specific configurations will sometimes be described as a representative below for the sake of convenience, but the specific configuration described as the representative may be replaced with another corresponding specific configuration.

The replacement may span a plurality of embodiments. That is to say, configurations whose examples are shown in different embodiments may be combined with each other to produce similar effects.

According to the embodiments described above, the semiconductor device includes: the substrate 100 (or the substrate 100A); the at least one semiconductor element 41 (or semiconductor element 42); the P electrode 31 (or the P electrode 31A); the AC electrode 51; the first connecting electrode; and the second connecting electrode. The first connecting electrode herein corresponds to at least one of the AC electrode 52, the AC electrode 52A, the AC electrode 53, the AC electrode 53A, and the like, for example. The second connecting electrode corresponds to at least one of the N electrode 62, the N electrode 62A, the N electrode 63, the N electrode 63A, and the like, for example. The semiconductor element 41 is provided over the upper surface of the substrate 100. The P electrode 31 is electrically connected to the semiconductor element 41. The P electrode 31 is provided to extend outward from the first side surface of the substrate 100 in plan view. The AC electrode 51 is electrically connected to the semiconductor element 41. The AC electrode 51 is provided to extend outward from the second side surface opposite the first side surface in plan view. The AC electrode 52 is electrically connected to the semiconductor element 41 and the AC electrode 51. The AC electrode 52 is provided to extend outward from at least one of the third side surface intersecting with the first side surface and the fourth side surface opposite the third side surface in plan view. The N electrode 62 is electrically connected to the semiconductor element 41. The N electrode 62 is provided to extend outward from at least one of the third side surface and the fourth side surface in plan view. The AC electrode 52 does not overlap any of the P electrode 31 and the AC electrode 51 in plan view above the substrate 100. The N electrode 62 does not overlap any of the P electrode 31 and the AC electrode 51 in plan view above the substrate 100.

According to such a configuration, the AC electrode 52, the AC electrode 53, the N electrode 62, and the N electrode 63 each being the connecting electrode are provided on the side surfaces intersecting with the side surfaces on which the P electrode 31 and the AC electrode 51 are provided. This facilitates wiring while suppressing oscillation when the components are used by being connected in parallel. Furthermore, the AC electrode 52, the AC electrode 53, the N electrode 62, and the N electrode 63 being the connecting electrodes are each provided not to overlap any of the P electrode 31 and the AC electrode 51 in plan view above the substrate 100. This enables miniaturization of the device.

Similar effects can be produced when another configuration whose example is shown herein is added to the above-mentioned configuration as appropriate, that is, when another configuration herein not referred to as the above-mentioned configuration is added to the above-mentioned configuration as appropriate.

According to the embodiments described above, the semiconductor device includes the resin 80 (or the resin 80A and the resin 80B). The resin 80 is provided over the upper surface of the substrate 100 to cover the semiconductor element 41, a portion of the P electrode 31, a portion of the AC electrode 51, a portion of the AC electrode 52, and a portion of the N electrode 62. The AC electrode 52 does not overlap any of the P electrode 31 and the AC electrode 51 in plan view in the resin 80. The N electrode 62 does not overlap any of the P electrode 31 and the AC electrode 51 in plan view in the resin 80. According to such a configuration, the AC electrode 52, the AC electrode 53, the N electrode 62, and the N electrode 63 are each provided not to overlap any of the P electrode 31 and the AC electrode 51 in plan view in the resin 80. This enables miniaturization of the device.

According to the embodiments described above, the semiconductor device includes the N electrode 61 (or the N bus bar 70, the N bus bar 70A, the N bus bar 72, and the N bus bar 74) electrically connected to the semiconductor element 41 and provided to extend outward from the first side surface in plan view. The N electrode 62 is electrically connected to the N electrode 61. According to such a configuration, the AC electrode 52, the AC electrode 53, the N electrode 62, and the N electrode 63 are each provided not to overlap any of the P electrode 31, the AC electrode 51, and the N electrode 61 in plan view above the substrate 100. This enables miniaturization of the device.

According to the embodiments described above, the resin 80 is provided to cover a portion of the N electrode 61. The AC electrode 52 does not overlap the N electrode 61 in plan view in the resin 80. The N electrode 62 does not overlap the N electrode 61 in plan view in the resin 80. According to such a configuration, the AC electrode 52, the AC electrode 53, the N electrode 62, and the N electrode 63 are each provided not to overlap any of the P electrode 31, the AC electrode 51, and the N electrode 61 in plan view in the resin 80. This enables miniaturization of the device.

According to the embodiments described above, the N bus bar 70 is disposed over the upper surface of the resin 80. According to such a configuration, the N bus bar 70 is located at the top of the semiconductor device, so that the N bus bar 70 over the upper surface of the resin 80 is the flat plate parallel to the wiring in the resin 80. Inductance can thereby be suppressed.

According to the embodiments described above, the resin 80A has at least one protrusion 82 on the upper surface thereof. The N bus bar 70A has at least one hole 70B into which the protrusion 82 is fitted at a position where the N bus bar 70A overlaps the protrusion 82 in plan view. According to such a configuration, the relative positions of the N bus bar 70A and the resin 80A are easily determined by the holes 70B and the protrusions 82, so that misalignment in assembly of the semiconductor device can be suppressed.

According to the embodiments described above, the resin 80B has at least one guide 84 on the upper surface thereof. The N bus bar 74 over the upper surface of the resin 80B is disposed adjacent to the guide 84 in plan view. According to such a configuration, the N bus bar 74 is easily positioned by being fitted between the guides 84, so that misalignment in assembly of the semiconductor device can be suppressed. The insulating strength can be improved when the long creepage distance between the N bus bar 74 and the AC electrode is maintained by forming the guides 84.

According to the embodiments described above, the N bus bar 70 provided to extend from the first side surface is adjacent to the P electrode 31 provided to extend from the first side surface in plan view. According to such a configuration, the N bus bar 70 is located at the top of the semiconductor device, so that the N bus bar 70 over the upper surface of the resin 80 is the flat plate parallel to the wiring in the resin 80. Inductance can thereby be suppressed.

According to the embodiments described above, the N bus bar 72 provided to extend from the first side surface overlaps the P electrode 31A provided to extend from the first side surface in plan view. According to such a configuration, inductance can effectively be suppressed. Furthermore, the P electrode 31A and the N bus bar 72 are located to overlap each other outside the frame of the first side surface to enable miniaturization of the device.

According to the embodiments described above, the substrate 100 includes a plurality of substrates 100. The semiconductor element 41, the P electrode 31, the AC electrode 51, the AC electrode 52, and the N electrode 62 are provided to each of the substrates 100. The plurality of substrates 100 include a first substrate and a second substrate arranged adjacent to each other. The first substrate and the second substrate are arranged so that the fourth side surface of the first substrate and the third side surface of the second substrate oppose each other. The AC electrode 52 provided to extend outward from the fourth side surface of the first substrate in plan view and the AC electrode 52 provided to extend outward from the third side surface of the second substrate in plan view are connected. The N electrode 62 provided to extend outward from the fourth side surface of the first substrate in plan view and the N electrode 62 provided to extend outward from the third side surface of the second substrate in plan view are connected. According to such a configuration, the AC electrode 52 and the AC electrode 53 of the adjacent power device modules are connected, and the N electrode 62 and the N electrode 63 of the adjacent power device modules are connected to reduce a potential difference between semiconductor elements of the power device modules connected in parallel, so that oscillation of the semiconductor elements can be suppressed.

According to the embodiments described above, at least one of the AC electrode 52 and the N electrode 62 is not provided to extend from at least one of the third side surface of the first substrate and the fourth side surface of the second substrate. According to such a configuration, the N electrode and the AC electrode are not provided to a surface not opposing an adjacent power device module, so that good insulation of the surface can be maintained. Even when another device is disposed to oppose the surface to which the N electrode and the AC electrode are not provided, there is no need to separately consider the insulating distance, so that an increase in size of the device can be suppressed.

According to the embodiments described above, at least one of the AC electrode 52 and the N electrode 63A provided to extend outward from the fourth side surface in plan view has the bend 63B outside the resin 80. The bend 63B bends the end extending outward from the fourth side surface in plan view to a side of the upper surface of the substrate 100. According to such a configuration, when semiconductor devices are arranged adjacent to each other, a height of a joint between electrodes of the adjacent semiconductor devices can be reduced. Good insulation between the part installed at the top of the semiconductor device and the N electrode 63A can thus be maintained by ensuring a sufficient insulating distance.

According to the embodiments described above, a semiconductor of the semiconductor element 41 includes SiC. According to such a configuration, SiC is used for the semiconductor of the semiconductor element to reduce a size of the element compared with a case where an Si element is used. The size of the semiconductor device can thereby be reduced. When the size of the semiconductor device is reduced, a wiring distance between the semiconductor elements for use in parallel connection is reduced to reduce a potential distance between the semiconductor elements.

### Modifications of Embodiments Described Above

In the embodiments described above, material properties of, materials for, dimensions of, shapes of, a relative positional relationship among, or conditions for performance of components are sometimes described, but they are each one example in all aspects, and are not restrictive.

Numerous modifications and the equivalent whose examples are not shown are thus devised within the scope of technology disclosed herein. For example, a case where at least one component is modified, added, or omitted and, further, a case where at least one component in at least one embodiment is extracted to be combined with components in another embodiment are included.

In a case where a name of a material and the like are described in the embodiments described above without being particularly designated, an alloy and the like containing an additive in addition to the material may be included unless any contradiction occurs.

“One” component in the embodiments described above may include “one or more” components unless any contradiction occurs.

Furthermore, each component in the embodiments described above is a conceptual unit, and a case where one component includes a plurality of structures, a case where one component corresponds to a portion of a structure, and a case where a plurality of components are included in one structure are included within the scope of technology disclosed herein.

Each component in the embodiments described above includes a structure having another structure or shape as long as the same function is fulfilled.

Description made herein is referred to for all the purposes relating to the present technology and is not admitted to be prior art.

### EXPLANATION OF REFERENCE SIGNS

31 P electrode, 31A P electrode, 41 semiconductor element, 42 semiconductor element, 51 AC electrode, 52 AC electrode, 52A AC electrode, 53 AC electrode, 53A AC electrode, 61 N electrode, 62 N electrode, 62A N electrode, 63 N electrode, 63A N electrode, 70B hole, 80 resin, 80A resin, 80B resin, 82 protrusion, 84 guide, 100 substrate, 100A substrate, 131 P electrode, 151 AC electrode, 161 N electrode.

1. A semiconductor device comprising:
a substrate;
at least one semiconductor element provided over an upper surface of the substrate;
a P electrode electrically connected to the semiconductor element and provided to extend outward from a first side surface of the substrate in plan view;
an AC electrode electrically connected to the semiconductor element and provided to extend outward from a second side surface opposite the first side surface in plan view;
a first connecting electrode electrically connected to the semiconductor element and the AC electrode and provided to extend outward from at least one of a third side surface intersecting with the first side surface and a fourth side surface opposite the third side surface in plan view; and
a second connecting electrode electrically connected to the semiconductor element and provided to extend outward from at least one of the third side surface and the fourth side surface in plan view, wherein
the first connecting electrode does not overlap any of the P electrode and the AC electrode in plan view above the substrate, and
the second connecting electrode does not overlap any of the P electrode and the AC electrode in plan view above the substrate.

2. The semiconductor device according to claim 1, further comprising
a resin provided over the upper surface of the substrate to cover the semiconductor element, a portion of the P electrode, a portion of the AC electrode, a portion of the first connecting electrode, and a portion of the second connecting electrode, wherein
the first connecting electrode does not overlap any of the P electrode and the AC electrode in plan view in the resin, and
the second connecting electrode does not overlap any of the P electrode and the AC electrode in plan view in the resin.

3. The semiconductor device according to claim 2, further comprising
an N electrode electrically connected to the semiconductor element and provided to extend outward from the first side surface in plan view, wherein
the second connecting electrode is electrically connected to the N electrode.

4. The semiconductor device according to claim 3, wherein
the resin is provided to cover a portion of the N electrode,
the first connecting electrode does not overlap the N electrode in plan view in the resin, and
the second connecting electrode does not overlap the N electrode in plan view in the resin.

5. The semiconductor device according to claim 3, wherein
the N electrode is disposed over an upper surface of the resin.

6. The semiconductor device according to claim 5, wherein
the resin has at least one protrusion on the upper surface thereof, and
the N electrode has at least one hole into which the protrusion is fitted at a position where the N electrode overlaps the protrusion in plan view.

7. The semiconductor device according to claim 5, wherein
the resin has at least one guide on the upper surface thereof, and
the N electrode over the upper surface of the resin is disposed adjacent to the guide in plan view.

8. The semiconductor device according to claim 3, wherein
the N electrode provided to extend from the first side surface is adjacent to the P electrode provided to extend from the first side surface in plan view.

9. The semiconductor device according to claim 3, wherein
the N electrode provided to extend from the first side surface overlaps the P electrode provided to extend from the first side surface in plan view.

10. The semiconductor device according to claim 1, wherein
the substrate comprises a plurality of substrates,
the semiconductor element, the P electrode, the AC electrode, the first connecting electrode, and the second connecting electrode are provided to each of the substrates,
the plurality of substrates include a first substrate and a second substrate arranged adjacent to each other,
the first substrate and the second substrate are arranged so that the fourth side surface of the first substrate and the third side surface of the second substrate oppose each other,
the first connecting electrode provided to extend outward from the fourth side surface of the first substrate in plan view and the first connecting electrode provided to extend outward from the third side surface of the second substrate in plan view are connected, and
the second connecting electrode provided to extend outward from the fourth side surface of the first substrate in plan view and the second connecting electrode provided to extend outward from the third side surface of the second substrate in plan view are connected.

11. The semiconductor device according to claim 10, wherein
at least one of the first connecting electrode and the second connecting electrode is not provided to extend from at least one of the third side surface of the first substrate and the fourth side surface of the second substrate.

12. The semiconductor device according to claim 1, wherein
at least one of the first connecting electrode and the second connecting electrode provided to extend outward from the fourth side surface in plan view has a bend outside the resin, and
the bend bends an end extending outward from the fourth side surface in plan view to a side of the upper surface of the substrate.

13. The semiconductor device according to claim 1, wherein
a semiconductor of the semiconductor element comprises SiC.
